(19) United States
(12) Patent Application Publication
(10) Pub. No.: US 2025/0174600 A1
(43) Pub. Date: May 29, 2025

(54) SEMICONDUCTOR PACKAGE

(71) Applicant: Samsung Electronics Co., Ltd., Suwon-si (KR)

(72) Inventor: Donghoon WON, Suwon-si (KR)

(73) Assignee: Samsung Electronics Co., Ltd., Suwon-si (KR)

(21) Appl. No.: 18/772,450

(22) Filed: Jul. 15, 2024

(30) Foreign Application Priority Data
Nov. 27, 2023 (KR) 10-2023-0167153

(51) Int. Cl. H01L 25/065; H01L 23/00; H01L 23/13; H01L 23/31; H01L 23/498; H01L 23/538; H10B 80/00

(52) U.S. Cl. CPC H01L 25/0657; H01L 23/13; H01L 24/32; H01L 24/33; H01L 24/48; H01L 24/73; H01L 23/3107; H01L 23/49816; H01L 23/5383; H01L 2224/32145; H01L 2224/32225; H01L 2224/33181; H01L 2224/48227; H01L 2224/73265; H01L 2225/06562; H10B 80/00

(57) ABSTRACT

Semiconductor packages and manufacturing methods thereof are provided. For example, a semiconductor package includes a first semiconductor chip, a second semiconductor chip on the first semiconductor chip, an adhesive film between the first semiconductor chip and the second semiconductor chip, and a molding layer covering a sidewall of the first semiconductor chip, a sidewall of the second semiconductor chip, and a sidewall of the adhesive film, wherein the second semiconductor chip includes a recess, a thickness of the portion of the second semiconductor chip that overlaps the recess in a vertical direction is less than a thickness of the remaining portion of the second semiconductor chip, the recess overlaps an upper portion of the first semiconductor chip in a horizontal direction, and the molding layer overlaps a lower portion of the first semiconductor chip in the horizontal direction.

### CROSS-REFERENCE TO RELATED APPLICATION

This application claims priority under 35 U.S.C. § 119 to Korean Patent Application No. 10-2023-0167153, filed on Nov. 27, 2023, in the Korean Intellectual Property Office, the disclosure of which is incorporated by reference herein in its entirety.

### BACKGROUND

The inventive concepts relate to semiconductor packages, and more particularly, to multi-chip semiconductor packages (MCP) including a plurality of semiconductor chips.

As the electronics industry develops rapidly, electronic devices are becoming more compact, multi-functional, and high-capacity in response to user demands. Accordingly, a semiconductor package including a plurality of semiconductor chips is required, and recently, a semiconductor package with a three-dimensional stacked structure in which a plurality of semiconductor chips are stacked in a vertical direction has been used.

### SUMMARY

Some example embodiments of the inventive concepts provide semiconductor packages including a plurality of semiconductor chips with improved integration.

However, problems to be solved by the inventive concepts are not limited to the problems mentioned above, and other problems may be clearly understood by those skilled in the art from the description below.

According to an example embodiment of the inventive concepts, a semiconductor package includes a first semiconductor chip, a second semiconductor chip on the first semiconductor chip, an adhesive film between the first semiconductor chip and the second semiconductor chip, and a molding layer covering a sidewall of the first semiconductor chip, a sidewall of the second semiconductor chip, and a sidewall of the adhesive film, wherein the second semiconductor chip includes a recess, the recess overlaps an upper portion of the first semiconductor chip in a horizontal direction, and the molding layer overlaps a lower portion of the first semiconductor chip in the horizontal direction.

According to an example embodiment of the inventive concepts, a semiconductor package includes a package substrate, a first semiconductor chip on an upper surface of the package substrate, a first adhesive film between the upper surface of the package substrate and a lower surface of the first semiconductor chip, a second semiconductor chip on an upper surface of the first semiconductor chip, and a second adhesive film between the upper surface of the first semiconductor chip and a lower surface of the second semiconductor chip, wherein the first semiconductor chip includes a first conductive pad on the upper surface of the first semiconductor chip, the second semiconductor chip includes a second conductive pad on the upper surface of the second semiconductor chip, and at least a portion of the first semiconductor chip overlaps the second semiconductor chip in a horizontal direction.

According to an example embodiment of the inventive concepts, a semiconductor package includes a package substrate, a first semiconductor chip on the package substrate, a second semiconductor chip on the first semiconductor chip, and a third semiconductor chip on the second semiconductor chip, wherein a horizontal width of the first semiconductor chip is less than a horizontal width of the second semiconductor chip, the horizontal width of the second semiconductor chip is same as a horizontal width of the third semiconductor chip, the second semiconductor chip overlaps an upper portion of the first semiconductor chip in a horizontal direction, and the third semiconductor chip overlaps an upper portion of the second semiconductor chip in the horizontal direction.

### BRIEF DESCRIPTION OF THE DRAWINGS

Example embodiments of the inventive concepts will be more clearly understood from the following detailed description taken in conjunction with the accompanying drawings in which:

FIG. 1A is a cross-sectional view illustrating a semiconductor package according to an example embodiment;

FIG. 1B is an enlarged view showing an area EX in FIG. 1A;

FIG. 2 is a layout illustrating a semiconductor package according to an example embodiment;

FIG. 3 is a diagram illustrating a semiconductor package according to an example embodiment;

FIG. 4 is a diagram for explaining a semiconductor package according to an example embodiment;

FIG. 5 is a cross-sectional view illustrating a semiconductor package according to an example embodiment;

FIG. 6 is a layout for explaining a semiconductor package according to an example embodiment;

FIGS. 7, 8, 9, 10, 11, and 12 are cross-sectional views sequentially shown in process order to explain a method of manufacturing a semiconductor package according to an example embodiment;

FIG. 13 is a diagram for explaining a semiconductor package according to an example embodiment; and

FIG. 14 is a diagram for explaining a semiconductor package according to an example embodiment.

### DETAILED DESCRIPTION

Hereinafter, some example embodiments of the inventive concepts are described in detail with reference to the accompanying drawings. The same reference numerals are used for the same components in the drawings, and the descriptions already given for the same components are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

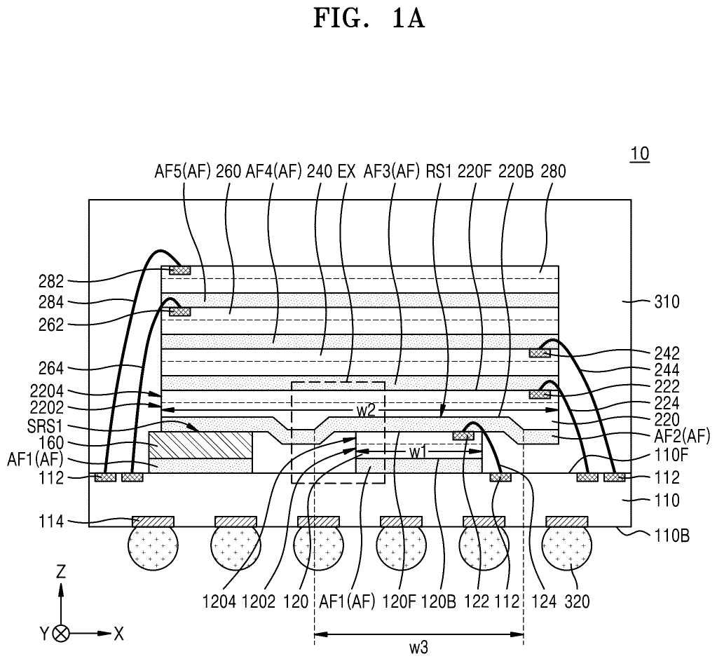

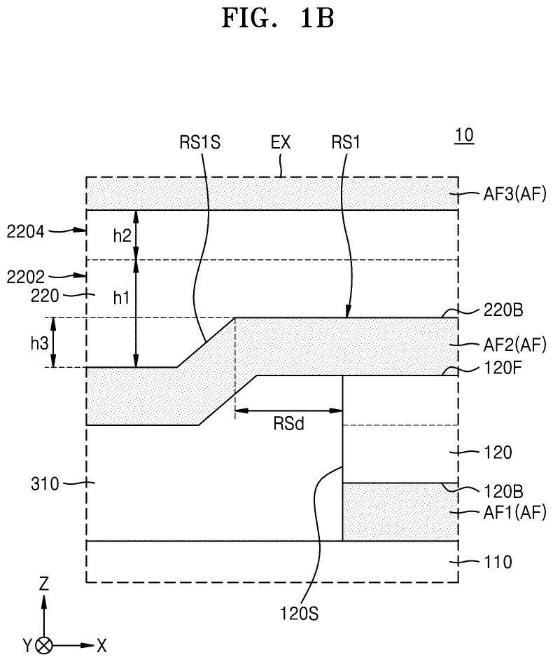

FIG. 1A is a cross-sectional view illustrating a semiconductor package according to an example embodiment.

FIG. 1B is an enlarged view showing an area EX in FIG. 1A.

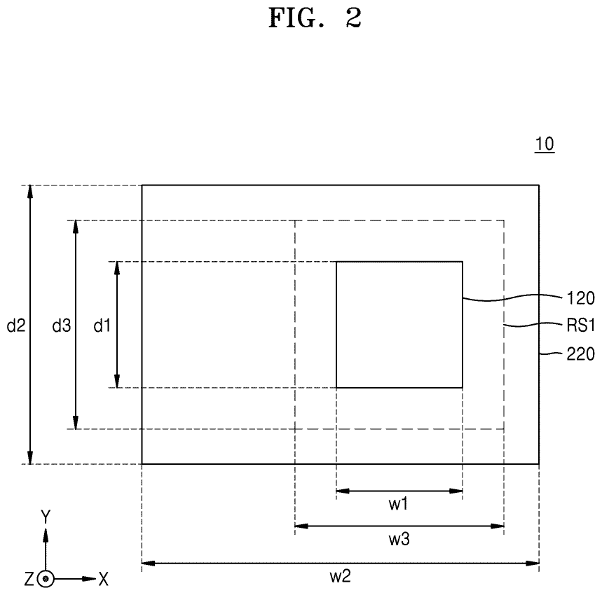

FIG. 2 is a layout illustrating a semiconductor package according to an example embodiment.

Referring to FIGS. 1A, 1B and 2, a semiconductor package 10 may include a package substrate 110, a first semiconductor chip 120, a second semiconductor chip 220, a third semiconductor chip 240, a fourth semiconductor chip 260, and a fifth semiconductor chip 280. The semiconductor package 10 may be a multi-chip package (MCP) including a plurality of semiconductor chips.

The package substrate 110 may include a first surface 110F on which the first semiconductor chip and the second to fifth semiconductor chips 220, 240, 260, and 280 are mounted, and a second surface 110B opposite to the first surface 110F. Hereinafter, a direction parallel to the first surface 110F of the package substrate 110 is defined as a first horizontal direction (e.g., X direction) and/or a second horizontal direction (e.g., Y direction), and a direction perpendicular to the first surface 110F of the package substrate 110 is defined as a vertical direction (e.g., Z direction). In this case, the first horizontal direction (e.g., X direction) may intersect with the second horizontal direction (e.g., Y direction). In addition, hereinafter, the horizontal width of any member may mean the length in the horizontal direction (e.g., X direction and/or Y direction), and the thickness or vertical height of any member may mean the length in the vertical direction (e.g., Z direction).

The package substrate 110 may include a plurality of conductive pads 112 disposed on the first surface 110F of the package substrate 110 and a plurality of external terminal pads 114 disposed on the second surface 110B of the package substrate 110. The package substrate 110 may be a double-sided printed circuit board. However, the package substrate 110 is not limited to a double-sided printed circuit board and may be a multi-layer printed circuit board.

The semiconductor package 10 may include five semiconductor chips, including the first semiconductor chip 120 and the second to fifth semiconductor chips 220, 240, 260, and 280 stacked in the vertical direction (e.g., Z direction) on the first semiconductor chip 120, but the number of semiconductor chips that may be included in the semiconductor package 10 is not limited thereto.

In some example embodiments, the footprint of a first semiconductor chip 120 may be less than footprints of the second to fifth semiconductor chips 220, 240, 260, and 280. For example, the horizontal width of the first semiconductor chip 120 may be less than the horizontal width of each of the second to fifth semiconductor chips 220, 240, 260, and 280. Within the semiconductor package 10, the sidewalls of the first semiconductor chip 120 and the sidewalls of the second to fifth semiconductor chips 220, 240, 260, and 280 may be disposed on different planes.

In some example embodiments, the footprints of each of the second to fifth semiconductor chips 220, 240, 260, and 280 may be substantially the same. For example, the horizontal widths of the second to fifth semiconductor chips 220, 240, 260, and 280 may be substantially equal to each other. Within the semiconductor package 10, sidewalls of the second to fifth semiconductor chips 220, 240, 260, and 280 may be aligned on substantially the same plane.

The sidewall of the first semiconductor chip 120 may overlap the second to fifth semiconductor chips 220, 240, 260, and 280 in the vertical direction (e.g., Z direction), and sidewalls of the second to fifth semiconductor chips 220, 240, 260, and 280 may overlap the package substrate 110 in a vertical direction (e.g., Z direction).

In some example embodiments, the first semiconductor chip 120 and the second to fifth semiconductor chips 220, 240, 260, and 280 may include different types of semiconductor chips. For example, the first semiconductor chip 120 may be a logic chip, and the second to fifth semiconductor chips 220, 240, 260, and 280 may be memory chips. When logic chips are stacked on or above a plurality of memory chips, the length of the wire for electrically connecting the logic chip to a package substrate becomes long, which may deteriorate the operating characteristics of the device. Thus, the logic chips may be stacked under a plurality of memory chips. For example, the logic chip may be a central processing unit (CPU) chip, a graphics processing unit (GPU) chip, or an application processor (AP) chip.

In some example embodiments, the first semiconductor chip 120 may be a volatile memory semiconductor chip such as dynamic random access memory (DRAM), and the second to fifth semiconductor chips 220, 240, 260, and 280 are non-volatile memory semiconductor chips and may be flash memory chips, for example, NAND flash memory chips).

An adhesive film AF may be provided between the package substrate 110 and the first semiconductor chip 120, between the package substrate 110 and a support member 160, and between the first to fifth semiconductor chips 120, 220, 240, 260, and 280 to provide bond therebetween. In some example embodiments, the adhesive film AF may be a die adhesive film (DAF) or a film over wire (FOW). In some example embodiments, the adhesive film AF may include an inorganic adhesive or a polymer adhesive. The polymer adhesive may broadly include thermosetting polymer adhesives and thermoplastic polymer adhesives. The thermosetting polymer adhesive may have a three-dimensional cross-link structure after the monomer is heat-molded and may not soften even when reheated. The thermoplastic polymer adhesive may have a linear polymer structure and may have the property of softening when reheated. In addition, in other example embodiments, the adhesive film AF may include a hybrid adhesive in which an inorganic adhesive and a polymer adhesive are mixed together.

The first semiconductor chip 120 may have a first surface 120F and a second surface 120B opposite to the first surface 120F. The first semiconductor chip 120 may be bonded to the package substrate 110 through the first adhesive film AF1 such that the second surface 120B of the first semiconductor chip 120 faces the first surface 110F of the package substrate 110.

The first semiconductor chip 120 may include a first semiconductor substrate 1202 and a first semiconductor device layer 1204. The first semiconductor substrate 1202 may be disposed on or define the second surface 120B of the first semiconductor chip 120, and the first semiconductor device layer 1204 may be disposed on or define the first surface 120F of the first semiconductor chip 120.

The first semiconductor substrate 1202 may be a bulk wafer or a wafer including epitaxial growth. The first semiconductor substrate 1202 may include a group IV semiconductor material, a group III-V semiconductor material, or a group II-VI semiconductor material. The group IV semiconductor material may include, for example, silicon (Si), germanium (Ge), or silicon germanium (SiGe). The group III-V semiconductor material may include, for example, gallium arsenide (GaAs), indium phosphorus (InP), gallium phosphide (GaP), indium arsenide (InAs), indium antimony (InSb), or indium gallium arsenide (InGaAs). The group II-VI semiconductor material may include, for example, zinc telluride (ZnTe) or cadmium sulfide (CdS). The first semiconductor substrate 1202 may include a silver conductive region, for example, a well doped with an impurity, or a structure doped with an impurity. In addition, the first semiconductor substrate 1202 may have various isolation structures, such as shallow trench isolation (STI) structures. The first semiconductor substrate 1202 may have upper and lower surfaces opposite to each other. In this case, the upper surface of the first semiconductor substrate 1202 may be the active surface of the first semiconductor substrate 1202, and the lower surface of the first semiconductor substrate 1202 may be the inactive surface of the first semiconductor substrate 1202.

The first semiconductor device layer 1204 may be disposed on the first semiconductor substrate 1202. The first semiconductor device layer 1204 may include a front end of line (FEOL) structure formed on the upper surface of the first semiconductor substrate 1202 and a back end of line (BEOL) structure formed on the FEOL structure. The FEOL structure may include individual devices formed within the first semiconductor substrate 1202 and/or on the active surface of the first semiconductor substrate 1202. The individual devices may include microelectronic devices, for example, image sensors such as metal-oxide-semiconductor field effect transistor (MOSFET) sensors, system large scale integration (LSI) sensors, and CMOS imaging sensors (CISs), micro-electronic devices (MEMS), active devices, and/or passive devices. The BEOL structure may include a multi-layered wiring layer.

The first semiconductor chip 120 may include a first bonding pad 122 and a first wire 124 for electrically connecting the first bonding pad 122 to a corresponding conductive pad among a plurality of conductive pads 112 on the package substrate 110. For example, the first bonding pad 122 may be disposed on the first surface 120F of the first semiconductor chip 120, and the first wire 124 may extend from the first bonding pad 122 disposed on the first surface 120F of the first semiconductor chip 120 and contact the conductive pad 112 disposed on the first surface 110F of the package substrate 110.

The first bonding pad 122 may be electrically connected to the integrated circuit of the first semiconductor chip 120. The first bonding pad 122 may correspond to one of an I/O pad to which a data input/output (I/O) signal is transmitted, a DQS pad to which a data strobe (DQS) signal is transmitted, a CE pad to which a chip enable (CE) signal is transmitted, an RE pad to which a read enable (RE) signal is transmitted, a WE pad to which a write enable (WE) signal is transmitted, a CLE pad to which a command latch enable (CLE) signal is transmitted, an ALE pad to which an address latch enable (ALE) signal is transmitted, and/or an R/B pad to which a ready/busy (R/B) signal is transmitted. In some example embodiments, the first bonding pad 122 may include a Vcc pad that supplies a power voltage (e.g., a voltage between about 2.0 V and about 5.0 V) and/or a Vss pad that supplies a ground voltage to the first semiconductor chip 120.

The first bonding pad 122 and a corresponding conductive pad 112 among the plurality of conductive pads 112 may be electrically connected to each other by the first wire 124. The first wire 124 may be formed through a wire bonding process and may be a conductive wire including a conductive material such as gold (Au) or copper (Cu). In some example embodiments, the upper surface of the first bonding pad 122 may be covered by a second adhesive film AF2, and the first wire 124 may partially penetrate the second adhesive film AF2. A portion of the first wire 124 may be surrounded by the second adhesive film AF2, and the remaining portion of the first wire 124 may be surrounded by a molding layer 310.

The support member 160 may be disposed to be spaced apart from the first semiconductor chip 120 in the horizontal direction (e.g., X direction and/or Y direction). The support member 160 may be bonded to the package substrate 110 through a first adhesive film AF1. In some example embodiments, the support member 160 may be a dummy chip having a similar configuration to the first semiconductor chip 120. The support member 160 is for supporting the second to fifth semiconductor chips 220, 240, 260, and 280 together with the first semiconductor chip 120. When the second to fifth semiconductor chips 220, 240, 260, and 280 may be sufficiently supported by the first semiconductor chip 120, the support member 160 may be omitted.

In some example embodiments, the support member 160 may have substantially the same thickness as the first semiconductor chip 120. In other words, the upper surface of the support member 160 may be at substantially the same level as the upper surface of the first semiconductor chip 120 in the vertical direction (e.g., Z direction).

The second semiconductor chip 220 may have a first surface 220F and a second surface 220B opposite to the first surface 220F. The second semiconductor chip 220 may be bonded to the first semiconductor chip 120 through the second adhesive film AF2 such that the second surface 220B of the second semiconductor chip 220 faces the first surface 120F of the first semiconductor chip 120.

The second semiconductor chip 220 may include a second semiconductor substrate 2202 and a second semiconductor device layer 2204. The second semiconductor substrate 2202 may be disposed on or define the second surface 220B of the second semiconductor chip 220, and the second semiconductor device layer 2204 may be disposed on or define the first surface 220F of the second semiconductor chip 220. The second semiconductor substrate 2202 may be a bulk wafer or a wafer including epitaxial growth. The second semiconductor substrate 2202 may include a group IV semiconductor material, a group III-V semiconductor material, or a group II-VI semiconductor material. The second semiconductor substrate 2202 may include a conductive region, for example, a well doped with an impurity, or a structure doped with an impurity. In addition, the second semiconductor substrate 2202 may have various device isolation structures, such as a shallow device isolation (STI) structure. The second semiconductor substrate 2202 may have upper and lower surfaces opposite to each other. In this case, the upper surface of the second semiconductor substrate 2202 may be an active surface, and the lower surface of the second semiconductor substrate 2202 may be an inactive surface.

The second semiconductor device layer 2204 may be disposed on the second semiconductor substrate 2202. The second semiconductor device layer 2204 may include an FEOL structure formed on the upper surface of the second semiconductor substrate 2202 and a BEOL structure formed on the FEOL structure. The FEOL structure may include individual devices formed within the second semiconductor substrate 2202 and/or on the active surface of the second semiconductor substrate 2202. The BEOL structure may include a multi-layered wiring layer.

Like the second semiconductor chip 220, the third to fifth semiconductor chips 240, 260, and 280 may each have a first surface and a second surface opposite to the first surface. The first surface of each of the third to fifth semiconductor chips 240, 260, and 280 may be an upper surface of each of the third to fifth semiconductor chips 240, 260, and 280, and the second surface of each of the third to fifth semiconductor chips 240, 260, and 280 may be a lower surface of each of the third to fifth semiconductor chips 240, 260, and 280. In addition, the third to fifth semiconductor chips 240, 260, and 280 may include a semiconductor substrate (not shown) disposed on or defining the second surface of each of the third to fifth semiconductor chips 240, 260, and 280 and a semiconductor device layer (not shown) disposed on or defining the first surface of each of the third to fifth semiconductor chips 240, 260, and 280, similar to the second semiconductor chip 220.

In some example embodiments, the second semiconductor chip 220 and the third to fifth semiconductor chips 240, 260, and 280 may have different thicknesses. For example, the thickness of the second semiconductor chip 220 may be greater than the thickness of each of the third to fifth semiconductor chips 240, 260, and 280. The second semiconductor chip 220 supports the third to fifth semiconductor chips 240, 260, and 280 to which the greatest stress is applied, so the second semiconductor chip 220 may be formed to be relatively thick compared to the third to fifth semiconductor chips 240, 260, and 280.

The second semiconductor chip 220 may overlap the upper portion of the first semiconductor chip 120 in the horizontal direction (for example, in the X direction and/or Y direction). For example, the second semiconductor substrate 2202 of the second semiconductor chip 220 may overlap the upper portion of the first semiconductor chip 120 in the horizontal direction (e.g., X direction and/or Y direction). In addition, the second semiconductor chip 220 may overlap at least a portion of the first semiconductor chip 120 in a vertical direction (e.g., Z direction).

The second semiconductor chip 220 may include a recess RS1. The recess RS1 may be formed in the second surface 220B of the second semiconductor chip 220. The upper portion of the first semiconductor chip 120 may be disposed within the recess RS1. The recess RS1 may overlap the upper portion of the first semiconductor chip 120 in the horizontal direction (for example, the X direction and/or the Y direction) and may overlap at least a portion of the first semiconductor chip 120 in the vertical direction (e.g., Z direction).

A portion of the second semiconductor chip 220 that overlaps the recess RS1 in the vertical direction (e.g., Z direction) may be less than the thickness of the remaining portion of the second semiconductor chip 220. In other words, the level of the lower surface of the portion of the second semiconductor chip 220 that overlaps the recess RS1 in the vertical direction (e.g., Z direction) may be different from the level of the lower surface of the remaining portion of the second semiconductor chip 220 in the vertical direction (e.g., Z direction). For example, the level of the lower surface of the portion of the second semiconductor chip 220 that overlaps the recess RS1 in the vertical direction (e.g., Z direction) may be higher in the vertical direction than the level of the lower surface of the remaining portion of the second semiconductor chip 220. The level of the lower surface of the remaining portion of the second semiconductor chip 220 may be between the level of the lower surface of the portion of the second semiconductor chip 220 that overlaps the recess RS1 in the vertical direction (e.g., Z direction) and the level of the lower surface of the first semiconductor chip 120.

As illustrated in FIGS. 1A and 2, the horizontal width of the recess RS1 may be greater than the horizontal width of the first semiconductor chip 120 and may be less than the horizontal width of the second semiconductor chip 220. For example, the first horizontal width w3 of the recess RS1 in the first horizontal direction X may be greater than a first horizontal width w1 of the first semiconductor chip 120 and may be less than the first horizontal width w2 of the second semiconductor chip 220. The second horizontal width d3 of the recess RS1 in the second horizontal direction Y may be greater than the second horizontal width d1 of the first semiconductor chip 120 and may be less than the second horizontal width d2 of the second semiconductor chip 220.

As illustrated in FIGS. 1A and 1B, the vertical height h3 of the recess RS1 may be equal to or less than the vertical height h1 of the second semiconductor substrate 2202 of the second semiconductor chip 220. For example, the vertical height h3 of the recess RS1 may be equal to or less than the difference between the vertical height of the second semiconductor chip 220 and the vertical height h2 of the second semiconductor device layer 2204.

The sidewall (or alternatively, side or side boundary) RS1S of the recess RS1 may be spaced apart from the sidewall 120S of the first semiconductor chip 120 adjacent thereto in the horizontal direction (e.g., the X direction and/or the Y direction). In some example embodiments, the minimum separation distance RSd between the sidewall RS1S of the recess RS1 and the sidewall 120S of the first semiconductor chip 120 adjacent thereto may be within about 100 micrometers to about 300 micrometers. The minimum separation distance RSd of the sidewall RS1S of the recess RS1 may be formed considering a width to which the first wire 124 extends so that the first wire 124 may extend between the sidewall RS1S of the recess RS1 and the sidewall 120S of the first semiconductor chip 120 adjacent thereto. In some example embodiments, the second adhesive film AF2 may be spaced apart from (e.g., may not be in contact with) the sidewall 120S of the first semiconductor chip 120. In other example embodiments, the upper part of the sidewall 120S of the first semiconductor chip 120 may be in contact with the second adhesive film AF2, and the lower portion of the sidewall 120S of the first semiconductor chip 120 may be in contact with the molding layer 310.

In some example embodiments, the sidewall RS1S of the recess RS1 may extend diagonally between the horizontal direction (e.g., X direction and/or Y direction) and the vertical direction (e.g., Z direction). For example, the sidewall RS1S of the recess RS1 may be an inclined surface. The horizontal width of the recess RS1 may narrow from the bottom to the top (in other words, as narrows toward the second semiconductor device layer 2204), and the recess RS1 may be formed in a tapered shape.

However, the recess RS1 may be formed in other shapes depending on the location of the first semiconductor chip 120. In some example embodiments, when the first semiconductor chip 120 overlaps the second semiconductor chip 220 in the vertical direction (e.g., Z direction), the first semiconductor chip 120 overlaps the recess RS1 in the vertical direction (e.g., Z direction), and the sidewall of the first semiconductor chip 120 and the sidewall of the recess RS1 may be formed to be spaced apart from each other, but the sidewall of the recess RS1 may be formed to face the sidewall of the first semiconductor chip 120. However, in some other example embodiments, when a portion of the first semiconductor chip 120 overlaps the second semiconductor chip 220 in the vertical direction (e.g., Z direction), only a portion of the first semiconductor chip 120 overlaps the recess RS1 in a vertical direction, and only a portion of the sidewall of the first semiconductor chip 120 may be formed to face the sidewall of the recess RS1.

In addition, when the semiconductor package 10 further includes a support member 160, the second semiconductor chip 220 may further include a support recess SRS1. The support recess SRS1 may be formed in the second surface 220B of the second semiconductor chip 220. The upper portion of the support member 160 may be disposed within the support recess SRS1. The support recess SRS1 may overlap the upper part of the support member 160 in the horizontal direction (for example, in the X direction and/or Y direction) and may overlap the support member 160 in the vertical direction (e.g., Z direction). Because the support recess SRS1 may be configured similar to the recess RS1, a detailed description of the support recess SRS1 is omitted.

The second to fifth semiconductor chips 220, 240, 260, and 280 may include second to fifth bonding pads 222, 242, 262, and 282 and second to fifth wires 224, 244, 264, and 284, respectively, wherein the second to fifth wires 224, 244, 264, and 284 electrically connect the second to fifth bonding pads 222, 242, 262, and 282 to corresponding conductive pads 112 among a plurality of conductive pads 112 on the package substrate 110, respectively. The second to fifth bonding pads 222, 242, 262, and 282 may be disposed on the first surfaces of each of the second to fifth semiconductor chips 220, 240, 260, and 280, respectively. The second to fifth wires 224, 244, 264, and 284 extend from the second to fifth bonding pads 222, 242, 262, and 282, respectively, and contact corresponding ones of a plurality of conductive pads 112 disposed on the first surface 110F of the package substrate 110, respectively.

The second to fifth bonding pads 222, 242, 262, and 282 may be electrically connected to integrated circuits of the second to fifth semiconductor chips 220, 240, 260, and 280, respectively. The second to fifth bonding pads 222, 242, 262, and 282 may each correspond to one of an I/O pad to which a data I/O signal is transmitted, a DQS pad to which a DQS signal is transmitted, a CE pad to which a CE signal is transmitted, an RE pad to which an RE signal is transmitted, a WE pad to which a WE signal is transmitted, a CLE pad to which a CLE signal is transmitted, an ALE pad to which an ALE signal is transmitted, and/or an R/B pad to which an R/B signal is transmitted. In some example embodiments, the second to fifth bonding pads 222, 242, 262, and 282 may include a Vcc pad that supplies a power voltage (e.g., a voltage between about 2.0 V and about 5.0 V) and/or a Vss pad that supplies a ground voltage to the second to fifth semiconductor chips 220, 240, 260, and 280.

In some example embodiments, the second bonding pad 222 and the third bonding pad 242 may be disposed adjacent to one side of the package substrate 110, and the fourth bonding pad 262 and the fifth bonding pad 282 may be disposed adjacent to the other side of the package substrate 110 opposite to the one side of the package substrate 110. However, the arrangement structure of the second to fifth bonding pads 222, 242, 262, and 282 is not limited to that shown. In some example embodiments, the second to fourth bonding pads 222, 242, and 262 may be disposed adjacent to one side of the package substrate 110, and the fifth bonding pad 282 may be disposed adjacent to the other side of the package substrate 110 opposite to the one side of the package substrate 110. In some other example embodiments, the second to fifth bonding pads 222, 242, 262, and 282 may be disposed adjacent to one side of the package substrate 110.

The second to fifth bonding pads 222, 242, 262, and 282 and corresponding conductive pads 112 among the plurality of conductive pads 112 may be electrically connected to each other through the second to fifth wires 224, 244, 264, and 284. The second to fifth wires 224, 244, 264, and 284 may be formed through a wire bonding process and may be conductive wires including a conductive material such as gold (Au) or copper (Cu). In some example embodiments, the second to fifth wires 224, 244, 264, and 284 may partially penetrate the second to fifth adhesive films AF2, AF3, AF4, and AF5, respectively. A portion of each of the second to fifth wires 224, 244, 264, and 284 may be surrounded by the second to fifth adhesive films AF2, AF3, AF4, and AF5, respectively, and the remaining portion of each of the second to fifth wires 224, 244, 264, and 284 may be surrounded by the molding layer 310.

The semiconductor package 10 may include the first semiconductor chip 120, the support member 160, and the molding layer 310 covering the second to fifth semiconductor chips 220, 240, 260, and 280. For example, the molding layer 310 may be formed to cover the upper surface of the package substrate 110, the sidewall of the first semiconductor chip 120, the sidewall and the exposed upper surface of the support member 160, and the sidewalls of the second to fifth semiconductor chips 220, 240, 260, and 280. For example, the molding layer 310 may include insulating resin or epoxy molding compound (EMC).

The semiconductor package 10 may include a plurality of external connection terminals 320 configured to electrically connect the semiconductor package 10 to an external device. Each of the plurality of external connection terminals 320 may be disposed on a corresponding external terminal pad 114 among the plurality of external terminal pads 114. The plurality of external connection terminals 320 may include, for example, solder balls, solder bumps, pin grid arrays, lead grid arrays, conductive tabs, or combinations thereof.

When the second semiconductor chip 220 does not include the recess RS1, the total vertical height of the second semiconductor chip 220 inevitably contributes to the vertical height of the semiconductor package 10. Because the second semiconductor chip 220 stacked on the first semiconductor chip 120 in the semiconductor package 10 includes a recess RS1 at a position overlapping with the first semiconductor chip 120 in the vertical direction (e.g., Z direction), the vertical height of the semiconductor package 10 may be reduced by the vertical height of the recess RS1.

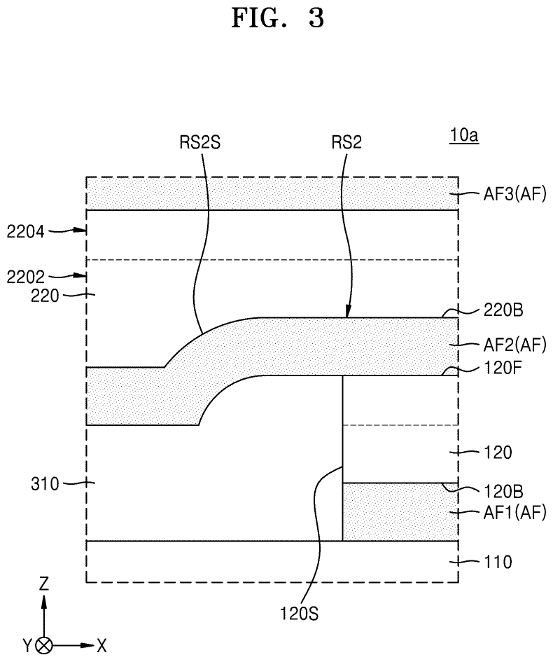

FIG. 3 is a diagram illustrating a semiconductor package 10a according to an example embodiment. FIG. 3 shows a portion corresponding to the area EX in FIG. 1A. Compared to the semiconductor package 10 described above with reference to FIGS. 1A, 1B, and 2, the semiconductor package 10a may be configured substantially similar to the semiconductor package 10 described above, except that the semiconductor package 10a includes a recess RS2 instead of the recess RS1. Therefore, the following focuses on explaining the differences between the semiconductor package 10 and the semiconductor package 10a.

Referring to FIG. 3, among the second to fifth semiconductor chips 220, 240, 260, and 280, the second semiconductor chip 220 may include a recess RS2. The recess RS2 may be formed on the second surface 220B of the second semiconductor chip 220. The upper portion of the first semiconductor chip 120 may be disposed within the recess RS2. The recess RS2 may overlap the upper portion of the first semiconductor chip 120 in a horizontal direction (e.g., X direction and/or Y direction) and may overlap the first semiconductor chip 120 in a vertical direction (e.g., Z direction).

A sidewall RS2S of the recess RS2 may be spaced apart from the sidewall 120S of the first semiconductor chip 120 in the horizontal direction (e.g., the X direction and/or the Y direction). In some example embodiments, the sidewall RS2S of the recess RS2 may extend diagonally between the horizontal direction (e.g., X direction and/or Y direction) and the vertical direction (e.g., Z direction). For example, the sidewall RS2S of the recess RS2 may have a curved surface. The horizontal width of the recess RS2 may gradually narrow from the bottom to the top (in other words, as narrows toward the second semiconductor device layer 2204). However, the recess RS2 may be formed in other shapes depending on the location of the first semiconductor chip 120.

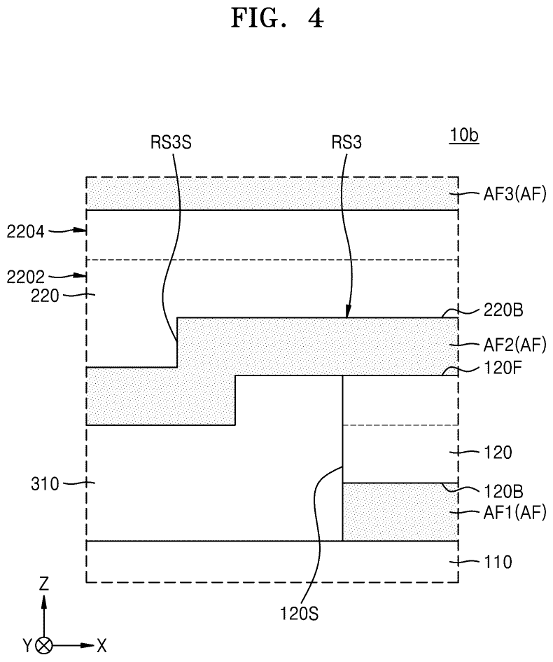

FIG. 4 is a diagram for explaining a semiconductor package according to an example embodiment. FIG. 4 shows a portion corresponding to the area EX in FIG. 1A. Compared to the semiconductor package 10 described above with reference to FIGS. 1A, 1B, and 2, a semiconductor package 10b may be configured substantially similar to the semiconductor package 10 described above, except that the semiconductor package 10b includes a recess RS3 instead of the recess RS1. Therefore, the following focuses on explaining the differences between the semiconductor package 10 and the semiconductor package 10b.

Referring to FIG. 3, among the second to fifth semiconductor chips 220, 240, 260, and 280, the second semiconductor chip 220 may include a recess RS3. The recess RS3 may be formed in the second surface 220B of the second semiconductor chip 220. The upper portion of the first semiconductor chip 120 may be disposed within the recess RS3. The recess RS3 may overlap the upper portion of the first semiconductor chip 120 in the horizontal direction (e.g., X direction and/or Y direction) and may overlap the first semiconductor chip 120 in the vertical direction (e.g., Z direction).

The sidewall RS3S of the recess RS3 may be spaced apart from the sidewall 120S of the first semiconductor chip 120 in the horizontal direction (e.g., the X direction and/or the Y direction). In some example embodiments, the sidewall RS3S of the recess RS3 may extend in the vertical direction (e.g., Z direction). For example, the sidewall RS3S of the recess RS3 may be flat. In other words, the sidewall RS3S of the recess RS3 and the second surface 220B of the second semiconductor chip 220 may form a step shape and the sidewall RS3S of the recess RS3 may extend along the sidewall 120S of the first semiconductor chip 120 to face the sidewall 120S of the first semiconductor chip 120. The horizontal width at the upper portion of the recess RS3 may be substantially equal to the horizontal width at the lower portion of the recess RS3. However, the recess RS3 may be formed in other shapes depending on the location of the first semiconductor chip 120.

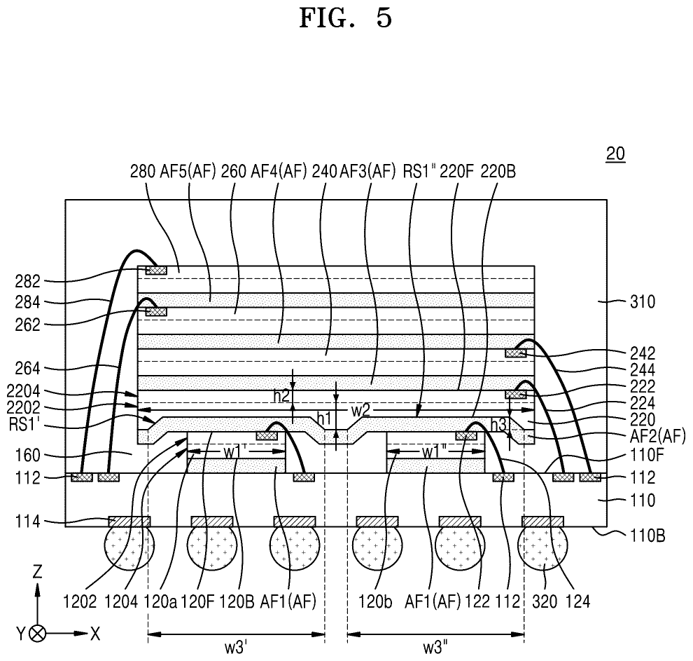

FIG. 5 is a cross-sectional view illustrating a semiconductor package 20 according to an example embodiment.

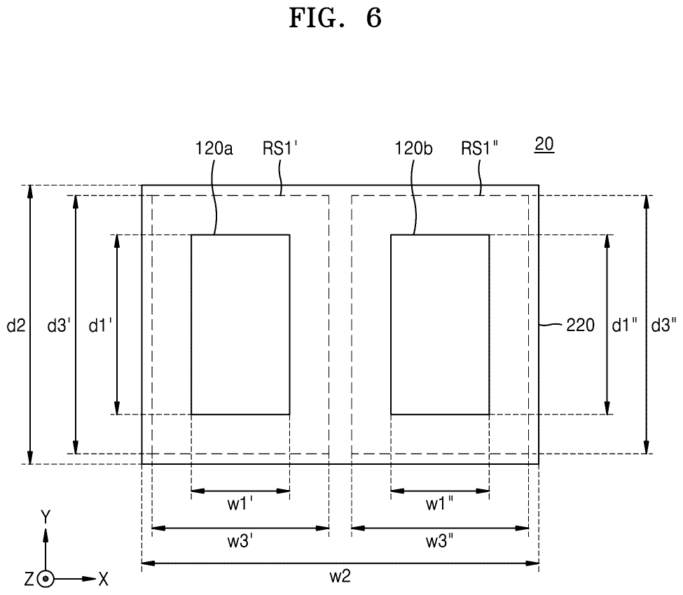

FIG. 6 is a layout for explaining the semiconductor package 20 according to an example embodiments.

Compared to the semiconductor package 10 described above with reference to FIGS. 1A, 1B, and 2, the semiconductor package 20 may be configured substantially similar to the semiconductor package 10 described above, except that the semiconductor package 20 includes a plurality of recesses RS1′ and RS1″. Therefore, the following focuses on explaining the differences between the semiconductor package 10 and the semiconductor package 20.

Referring to FIGS. 5 and 6, the semiconductor package 20 may include a package substrate 110, a plurality of first semiconductor chips 120a and 120b, and second to fifth semiconductor chips 220, 240, 260, and 280 mounted on the package substrate 110.

The semiconductor package 20 may include the plurality of first semiconductor chips 120a and 120b arranged to be spaced apart in a horizontal direction (e.g., X direction and/or Y direction). However, the number of first semiconductor chips (e.g., the plurality of first semiconductor chips 120a and 120b) arranged to be spaced apart in the horizontal direction (e.g., X direction and/or Y direction) is not limited to two as shown but may be three or more.

The footprint of each of the plurality of first semiconductor chips 120a and 120b may be smaller than the footprint of each of the second to fifth semiconductor chips 220, 240, 260, and 280. For example, the horizontal width of each of the plurality of first semiconductor chips 120a and 120b may be less than the horizontal width of each of the second to fifth semiconductor chips 220, 240, 260, and 280. Within the semiconductor package 20, the sidewalls of the second to fifth semiconductor chips 220, 240, 260, and 280 and the sidewalls of each of the plurality of first semiconductor chips 120a and 120b may be disposed on different planes. In some example embodiments, the footprints of the second to fifth semiconductor chips 220, 240, 260, and 280 may be substantially the same. For example, the horizontal widths of the second to fifth semiconductor chips 220, 240, 260, and 280 may be substantially equal to each other. Within the semiconductor package 20, sidewalls of the second to fifth semiconductor chips 220, 240, 260, and 280 may be aligned on substantially the same plane. For example, the sidewalls of the plurality of first semiconductor chips 120a and 120b may overlap the second to fifth semiconductor chips 220, 240, 260, and 280 in a vertical direction (e.g., Z direction), and the sidewalls of the second to fifth semiconductor chips 220, 240, 260, and 280 may overlap the package substrate 110 in the vertical direction (e.g., Z direction).

In some example embodiments, the plurality of first semiconductor chips 120a and 120b and the second to fifth semiconductor chips 220, 240, 260, and 280 may include different types of semiconductor chips. In some example embodiments, the plurality of first semiconductor chips 120a and 120b may be volatile memory semiconductor chips such as DRAM, and the second to fifth semiconductor chips 220, 240, 260, and 280 may be non-volatile memory semiconductor chips, for example, flash memory chips such as NAND flash memory chips.

The package substrate 110 and the plurality of first semiconductor chips 120a and 120b, the plurality of first semiconductor chips 120a and 120b and the second semiconductor chips 220, and each of the second to fifth semiconductor chips 220, 240, 260, and 280 may be bonded to each other by an adhesive film AF.

Each of the plurality of first semiconductor chips 120a and 120b may have a first surface 120F and a second surface 120B opposite to the first surface 120F. Each of the plurality of first semiconductor chips 120a and 120b may be bonded to the package substrate 110 through a plurality of first adhesive films AF1 such that the second surface 120B of each of the plurality of first semiconductor chips 120a and 120b faces the first surface 110F of the package substrate 110.

The plurality of first semiconductor chips 120a and 120b may each include a first semiconductor substrate 1202 and a first semiconductor device layer 1204. Each of the plurality of first semiconductor chips 120a and 120b may include a first bonding pad 122 and a first wire 124 connecting the first bonding pad 122 to a corresponding one of the plurality of conductive pads 112 on the package substrate 110. For example, the first bonding pad 122 may be disposed on the first surface 120F of each of the plurality of first semiconductor chips 120a and 120b, and the first wire 124 may extend from the first bonding pad 122 disposed on the first surface 120F of each of the plurality of first semiconductor chips 120a and 120b to contact the conductive pad 112 disposed on the first surface of the package substrate 110.

The second semiconductor chip 220 may be bonded to the plurality of first semiconductor chips 120a and 120b through a second adhesive film AF2 such that the second surface 220B of the second semiconductor chip 220 faces the first surface 120F of the plurality of first semiconductor chips 120a and 120b. The second semiconductor chip 220 may include a second semiconductor substrate 2202 and a second semiconductor device layer 2204.

The second semiconductor chip 220 may include a plurality of recess RS1′ and RS1″. The plurality of recesses RS1′ and RS1″ may be formed in the second surface 220B of the second semiconductor chip 220. The upper portions of each of the plurality of first semiconductor chips 120a and 120b may be disposed within the plurality of recesses RS1′ and RS1″. The plurality of recesses RS1′ and RS1″ may overlap the upper portions of the plurality of first semiconductor chips 120a and 120b in the horizontal direction (e.g., X direction and/or Y direction) and may overlap the plurality of first semiconductor chips 120a and 120b in the vertical direction (e.g., Z direction).

The thickness of a portion of the second semiconductor chip 220 that overlaps the plurality of recesses RS1′ and RS1″ in the vertical direction (e.g., Z direction) may be less than the thickness of the remaining portion of the second semiconductor chip 220. In other words, the level of the lower surface of the portion of the second semiconductor chip 220 that overlaps the plurality of recesses RS1′ and RS1″ in the vertical direction (e.g., Z direction) may be higher in the vertical direction (for example, Z direction) than the level the lower surface of the remaining portion of the semiconductor chip 220. The level of the lower surface of the remaining portion of the second semiconductor chip 220 may be between the level of the lower surface of the portion of the second semiconductor chip 220 that overlaps the plurality of recesses RS1′ and RS1″ in the vertical direction (e.g., Z direction) and the level of the lower surface of the first semiconductor chip 120. A detailed description of the shape of each of the plurality of recesses RS1′ and RS1″ is similar to the description of the recesses RS1 in FIGS. 1A, 1B, and 2.

The horizontal width of each of the plurality of recesses RS1′ and RS1″ may be greater than the horizontal width of each of the plurality of first semiconductor chips 120a and 120b and may be less than the horizontal width of the second semiconductor chip 220. For example, the first horizontal widths w3′ and w3″ of the plurality of recesses RS1′ and RS1″ in the first horizontal direction X may be greater than the first horizontal widths w1′ and w1″ of the plurality of first semiconductor chips 120a and 120b, respectively, and may be less than the first horizontal width w2 of the second semiconductor chip 220. The second horizontal widths d3′ and d3″ of the plurality of recesses RS1′ and RS1″ in the second horizontal direction Y may be greater than the second horizontal widths d1′ and d1″ of the plurality of first semiconductor chips 120a and 120b and may be less than the second horizontal width d2 of the second semiconductor chip 220. In some example embodiments, the first horizontal widths w1′ and w1″ of the plurality of first semiconductor chips 120a and 120b may be different, and accordingly, the first horizontal widths w3′ and w3″ of each of the plurality of recesses RS1′ and RS1″ may also be different, and are not necessarily limited to being the same. Likewise, in some example embodiments, the second horizontal widths d1′ and d1″ of the plurality of first semiconductor chips 120a and 120b may be different, and accordingly, the second horizontal widths d3′ and d3″ of each of the plurality of recesses RS1′ and RS1″ may also be different, and are not necessarily limited to being the same.

As illustrated in FIGS. 1A and 1B, the vertical height h3 of the plurality of recesses RS1′ and RS1″ may be equal to or less than the vertical height h1 of the second semiconductor substrate 2202 of the second semiconductor chip 220. For example, the vertical height h3 of the plurality of recesses RS1′ and RS1″ may be equal to or less than the difference between the vertical height of the second semiconductor chip 220 and the vertical height h2 of the second semiconductor device layer 2204.

The shapes of the plurality of recesses RS1′ and RS1″ may be different depending on the respective positions of the plurality of first semiconductor chips 120a and 120b, and are not necessarily limited to being the same. In some example embodiments, when the plurality of first semiconductor chips 120a and 120b overlap with the second semiconductor chip 220 in the vertical direction (for example, Z direction), each of the plurality of recesses RS1′ and RS1″ may have sidewalls facing the sidewalls of the plurality of first semiconductor chips 120a and 120b. However, in some other example embodiments, when a portion of any one of the plurality of first semiconductor chips 120a and 120b does not overlap the second semiconductor chip 220 in the vertical direction (for example, Z direction), each of the plurality of recesses RS1′ and RS1″ may have a sidewall that faces a portion of the sidewalls of the plurality of first semiconductor chips 120a and 120b that overlap in a vertical direction (e.g., Z direction) with the second semiconductor chip 220.

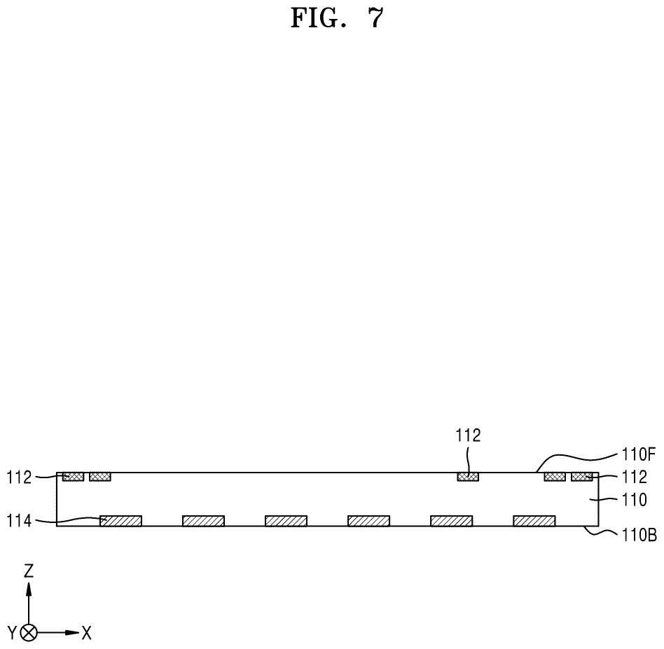

FIGS. 7, 8, 9, 10, 11, and 12 are cross-sectional views sequentially shown in process order to explain a method of manufacturing a semiconductor package according to an example embodiment.

Referring to FIG. 7, a package substrate 110 having a first surface 110F and a second surface 110B facing the first surface 110F may be provided. The package substrate 110 may include a plurality of conductive pads 112 disposed on the first surface 110F and a plurality of external terminal pads 114 disposed on the second surface 110B. The package substrate 110 may be a double-sided printed circuit board. However, the package substrate 110 is not limited to a double-sided printed circuit board and may be a multi-layer printed circuit board.

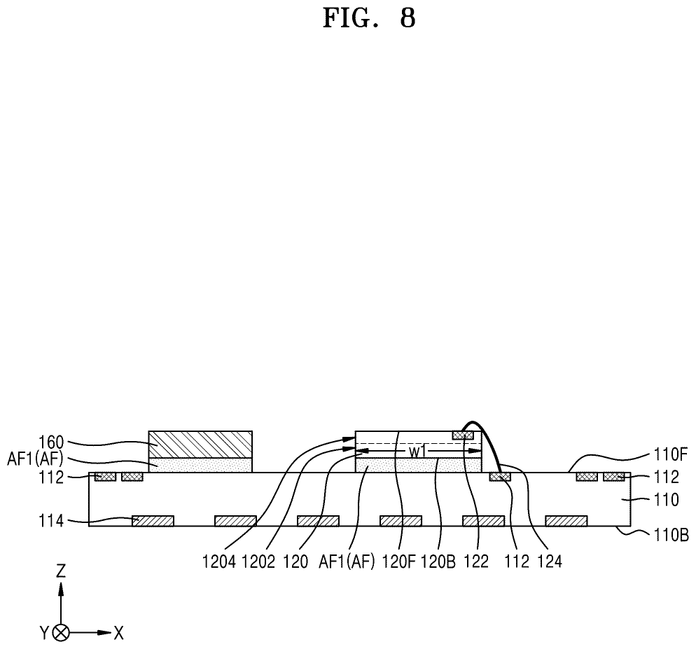

Referring to FIG. 8, a first semiconductor chip 120 and the support member 160 may be stacked on the package substrate 110 of FIG. 7. The first semiconductor chip 120 and the support member 160 may each be bonded to the package substrate 110 through a first adhesive film AF1. For example, the first semiconductor chip 120 may be bonded to the package substrate 110 through the first adhesive film AF1 such that a second surface 120B of the first semiconductor chip 120 faces the first surface 110F of the package substrate 110. After the first semiconductor chip 120 is bonded on the package substrate 110, the first bonding pad 122 may be bonded to a corresponding conductive pad 112 among a plurality of conductive pads 112 on the package substrate 110 using a first wire 124. The first wire 124 may be formed through a wire bonding process and may be a conductive wire containing a conductive material such as gold (Au) or copper (Cu).

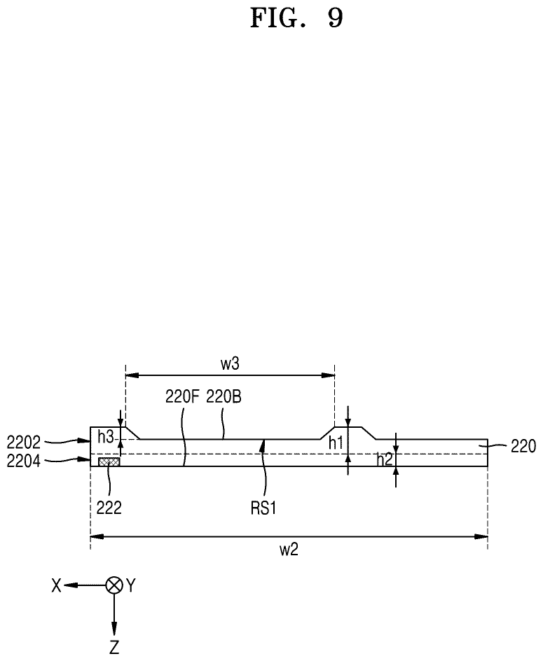

Referring to FIG. 9, in order to form a recess RS1 at a position corresponding to the first semiconductor chip 120 in FIG. 8 and a support recess SRS1 at a position corresponding to the support member, an etching process to remove a portion of a second semiconductor chip 220 may be performed on a second surface 220B of the second semiconductor chip 220. For example, the etching process may be performed using plasma.

The etching process may be performed on a second semiconductor substrate 2202 of the second semiconductor chip 220 and may be performed so that the second semiconductor device layer 2204 is exposed. In the recess RS1 and the support recess SRS1 formed through the etching process, a height h3 of the recess RS1 and a height h3 of the support recess SRS1 may be equal to or less than a height h1 of the second semiconductor substrate 2202. In other words, the height h3 of the recess RS1 and the height h3 of the support recess SRS1 may be equal to or less than the difference between the height of the second semiconductor chip 220 and a height h2 of the second semiconductor device layer 2204.

A horizontal width w3 of the recess RS1 may be greater than the horizontal width w1 of the first semiconductor chip 120 of FIG. 8 and less than a horizontal width w2 of the second semiconductor chip 220. For example, the horizontal width w3 of the recess RS1 may be formed by adding about 200 micrometers to about 600 micrometers to the horizontal width w1 of the first semiconductor chip 120 of FIG. 8. However, the horizontal width w3 of the recess RS1 is not limited to the above-mentioned values and may be formed to secure a separation distance between the sidewall of the recess RS1 and the sidewall of the first semiconductor chip 120 such that the first wire 124 connected to the first semiconductor chip 120 of FIG. 8 is not mechanically deformed.

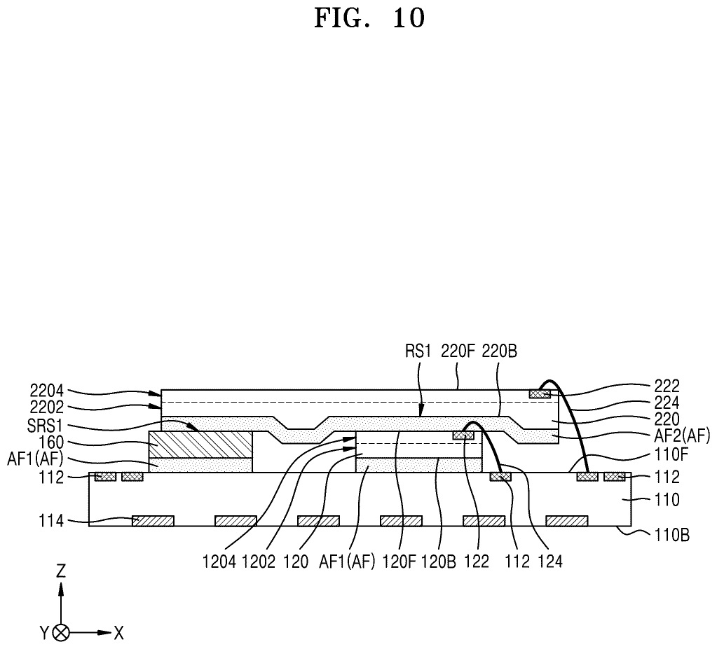

Referring to FIG. 10, a second semiconductor chip 220 in which the recess RS1 and the support recess SRS1 of FIG. 9 are formed may be stacked on a first semiconductor chip 120. The second semiconductor chip 220 may be bonded to the first semiconductor chip 120 through a second adhesive film AF2. For example, the second semiconductor chip 220 may be bonded onto the first semiconductor chip 120 through an adhesive film AF2 such that a second surface 220B of the second semiconductor chip 220 faces a first surface 120F of the first semiconductor chip 120.

In this case, because the second semiconductor chip 220 is bonded onto the first semiconductor chip to which the first wire 124 is bonded, in order to alleviate or prevent deformation of the looping shape of the first wire 124, the thickness of the adhesive film AF2 may be greater than the thickness of the looped portion of the first wire 124. A looped portion of the first wire 124 may partially penetrate the adhesive film AF2.

After the second semiconductor chip 220 is bonded onto the first semiconductor chip 120, the second bonding pad 222 may be bonded to a corresponding conductive pad 112 among a plurality of conductive pads 112 on the package substrate 110 using a second wire 224. The second wire 224 may be formed through a wire bonding process and may be a conductive wire including a conductive material such as gold (Au) or copper (Cu).

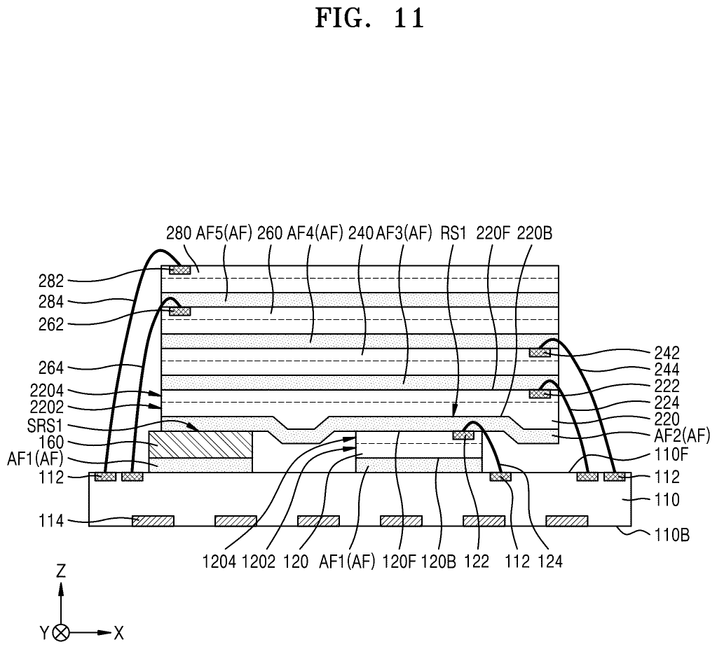

Referring to FIG. 11, the third to fifth semiconductor chips 240, 260, and 280 may be sequentially stacked on the second semiconductor chip 220. The third to fifth semiconductor chips 240, 260, and 280 may be bonded to the second to fourth semiconductor chips 220, 240, and 260 through third to fifth adhesive films AF3, AF4, and AF5, respectively. In this case, after the second wire 224 is bonded to the second semiconductor chip 220, the third semiconductor chip 240 is bonded to the second semiconductor chip 220 through the third adhesive film AF3, after the third wire 244 is bonded to the third semiconductor chip 240, the fourth semiconductor chip 260 is bonded to the third semiconductor chip 240 through the fourth adhesive film AF4, and after the fourth wire 264 is bonded, the fifth semiconductor chip 280 is bonded to the fourth semiconductor chip 260 through the fifth adhesive film AF5. In order to alleviate or prevent the looping shape of the second to fourth wires 224, 244, and 264 from being deformed, the thickness of the third to fifth adhesive films AF3, AF4, and AF5 may be greater than the thickness of the looped portion of the second to fourth wires 224, 244, and 264, respectively. The looped portions of the second to fourth wires 224, 244, and 264 may partially penetrate the third to fifth adhesive films AF3, AF4, and AF5, respectively.

In the bonding process of the third to fifth wires 244, 264, and 284, the third to fifth bonding pads 242, 262, and 282 may each be bonded to a corresponding conductive pad 112 among a plurality of conductive pads 112 on the package substrate using the third to fifth wires 244, 264, and 284. The third to fifth wires 244, 264, and 284 may be formed through a wire bonding process and may be conductive wires including a conductive material such as gold (Au) or copper (Cu).

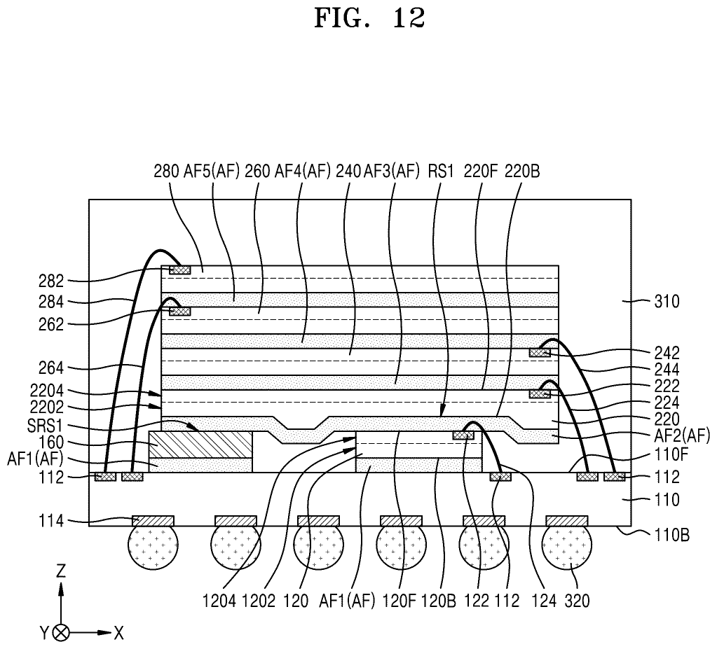

Referring to FIG. 12, a molding layer 310 covering the result of FIG. 11 may be formed, wherein the result of FIG. 11 may include the upper surface of the package substrate 110, the sidewall of the first semiconductor chip 120, the sidewall and exposed upper surface of the support member 160, and the sidewalls and upper surfaces of the second to fifth semiconductor chips 220, 240, 260, and 280. For example, the molding layer 310 may include insulating resin or EMC.

Then, a plurality of external connection terminals 320 configured to electrically connect an external device to the semiconductor package may be formed on the plurality of external terminal pads 114. The plurality of external connection terminals 320 may include, for example, solder balls, solder bumps, pin grid arrays, lead grid arrays, conductive tabs, or a combination thereof.

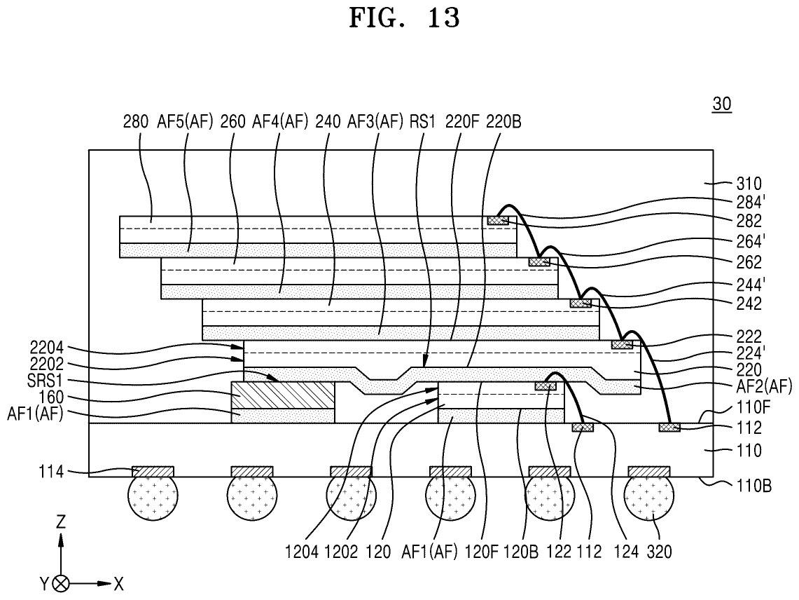

FIG. 13 is a diagram for explaining a semiconductor package according to an example embodiment.

Compared to the semiconductor package 10 described above with reference to FIGS. 1A, 1B, and 2, a semiconductor package 30 may be configured substantially similar to the semiconductor package 10 described above. Therefore, the following focuses on explaining the differences between the semiconductor package 10 and the semiconductor package 30.

Referring to FIG. 13, the semiconductor package 30 may include a package substrate 110, a first semiconductor chip 120, and second to fifth semiconductor chips 220, 240, 260, and 280. The semiconductor package 30 may be a MCP including a plurality of semiconductor chips.

In some example embodiments, the second to fifth semiconductor chips 220, 240, 260, and 280 may be stacked on the first semiconductor chip 120 in a step shape. For example, the second to fifth semiconductor chips 220, 240, 260, and 280 may be stacked in a cascade structure and may be sequentially offset. The form in which the second to fifth semiconductor chips 220, 240, 260, and 280 are stacked may not be limited to that shown. For example, among the second to fifth semiconductor chips 220, 240, 260, and 280, the lower second and third semiconductor chips 220 and 240 may be sequentially offset in a direction of one sidewall of the package substrate 110, and the upper fourth and fifth semiconductor chips 260 and 280 may be sequentially offset in a direction of the other sidewall opposite to the one sidewall of the package substrate 110.

Within the semiconductor package 30, sidewalls of the second to fifth semiconductor chips 220, 240, 260, and 280 may be disposed on different planes. For example, one sidewall of the second semiconductor chip 220 may be aligned on the package substrate 110, and the other sidewall of the second semiconductor chip 220 opposite to the one sidewall may be aligned on the support member 160. One sidewall of each of the third to fifth semiconductor chips 240, 260, and 280 may be aligned on the package substrate 110, and the other sidewall opposite to the one sidewall of each of the third to fifth semiconductor chips 240, 260, and 280 may be aligned on the second semiconductor chip 220.

The package substrate 110 and the first semiconductor chip 120, the first semiconductor chip 120 and the second semiconductor chip 220, the second semiconductor chip 220 and the third semiconductor chip 240, the third semiconductor chip 240 and the fourth semiconductor chip 260, and the fourth semiconductor chip 260 and the fifth semiconductor chip 280 may be bonded to each other by an adhesive film AF. However, the second adhesive film AF2 between the first semiconductor chip 120 and the second semiconductor chip 220 may have a different thickness than the first adhesive film AF1 between the package substrate 110 and the first semiconductor chip 120, a third adhesive film AF3 between the second semiconductor chip 220 and the third semiconductor chip 240, a fourth adhesive film AF4 between the third semiconductor chip 240 and the fourth semiconductor chip 260, and a fifth adhesive film AF5 between the fourth semiconductor chip 260 and the fifth semiconductor chip 280. For example, the second adhesive film AF2 may be thicker than the first adhesive film AF1 and the third to fifth adhesive films AF3, AF4, and AF5. The second adhesive film AF2 is configured to cover a portion of a first wire 124 to alleviate or prevent looping of the first wire 124 and may be relatively thick.

A first bonding pad 122 and a corresponding conductive pad 112 among the plurality of conductive pads 112 may be electrically connected to each other by the first wire 124. The first wire 124 may be formed through a wire bonding process and may be a conductive wire including a conductive material such as gold (Au) or copper (Cu). In embodiments, the first wire 124 may partially penetrate the first adhesive film AF1. A portion of the first wire 124 may be surrounded by the first adhesive film AF1, and the remaining portion of the first wire 124 may be surrounded by the molding layer 310.

Each of the second to fifth bonding pads 222, 242, 262, and 282 and a corresponding conductive pad 112 among the plurality of conductive pads 112 may be electrically connected to each other by the second to fifth wires 224′, 244′, 264′, and 284′. The second to fifth wires 224, 244, 264, and 284 may be formed through the wire bonding process and may be conductive wires including a conductive material such as gold (Au) or copper (Cu). In embodiments, the second to fifth wires 224′, 244′, 264′, and 284′ may be surrounded by the molding layer 310.

In some example embodiments, the second semiconductor chip 220 may include a recess RS1, and the upper portion of the first semiconductor chip 120 may be disposed within the recess RS1. The recess RS1 may overlap the top of the first semiconductor chip 120 in the horizontal direction (for example, the X direction and/or the Y direction) and may overlap the first semiconductor chip 120 in a vertical direction (e.g., Z direction). The detailed description of the recess RS1 is similar to that described above with reference to FIGS. 1A, 1B, and 2.

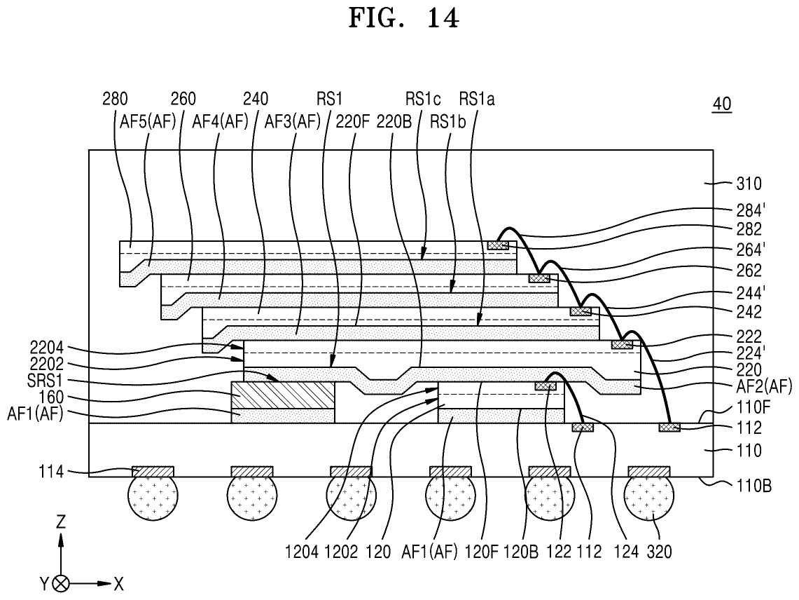

FIG. 14 is a diagram for explaining a semiconductor package 40 according to an example embodiment.

Compared to the semiconductor package 10 described above with reference to FIGS. 1A, 1B, and 2, the semiconductor package 40 is configured substantially similar to the semiconductor package 10. Therefore, the following focuses on explaining the differences between the semiconductor package 10 and the semiconductor package 40.

Referring to FIG. 14, the semiconductor package 40 may include a package substrate 110, a first semiconductor chip 120, and second to fifth semiconductor chips 220, 240, 260, and 280. The semiconductor package 30 may be a MCP including a plurality of semiconductor chips.

In some example embodiments, the second to fifth semiconductor chips 220, 240, 260, and 280 may be stacked on the first semiconductor chip 120 in a step shape. For example, the second to fifth semiconductor chips 220, 240, 260, and 280 may be stacked in a cascade structure and may be sequentially offset. The form in which the second to fifth semiconductor chips 220, 240, 260, and 280 are stacked may not be limited to that shown. For example, among the second to fifth semiconductor chips 220, 240, 260, and 280, the second semiconductor chip 220 and the third semiconductor chip 240 located in the lower portion thereof may be sequentially offset in the direction of one sidewall of the package substrate 110, and the fourth semiconductor chip 260 and the fifth semiconductor chip 280 located in the upper portion thereof may be sequentially offset in the direction of the other sidewall opposite to the one sidewall of the package substrate 110.

Within the semiconductor package 40, sidewalls of the second to fifth semiconductor chips 220, 240, 260, and 280 may be disposed on different planes. For example, one sidewall of the second semiconductor chip 220 may be aligned on the package substrate 110, and the other sidewall of the second semiconductor chip 220 opposite to the one sidewall may be aligned on the support member 160. One sidewall of each of the third to fifth semiconductor chips 240, 260, and 280 may be aligned on the package substrate 110, and the other sidewall opposite to the one sidewall of each of the third to fifth semiconductor chips 240, 260, and 280 may be aligned on the second semiconductor chip 220.

The package substrate 110 and the first semiconductor chip 120, the first semiconductor chip 120 and the second semiconductor chip 220, the second semiconductor chip 220 and the third semiconductor chip 240, the third semiconductor chip 240 and the fourth semiconductor chip 260, and the fourth semiconductor chip 260 and the fifth semiconductor chip 280 may be bonded to each other by an adhesive film AF. However, the second adhesive film AF2 between the first semiconductor chip 120 and the second semiconductor chip 220 may have a different thickness than the first adhesive film AF1 between the package substrate 110 and the first semiconductor chip 120, a third adhesive film AF3 between the second semiconductor chip 220 and the third semiconductor chip 240, a fourth adhesive film AF4 between the third semiconductor chip 240 and the fourth semiconductor chip 260, and a fifth adhesive film AF5 between the fourth semiconductor chip 260 and the fifth semiconductor chip 280. For example, the second adhesive film AF2 may be thicker than the first adhesive film AF1 and the third to fifth adhesive films AF3, AF4, and AF5. The second adhesive film AF2 is configured to cover a portion of the first wire 124 to prevent looping of the first wire 124 and may be relatively thick.

The first bonding pad 122 and a corresponding conductive pad 112 among the plurality of conductive pads 112 may be electrically connected to each other by the first wire 124. The first wire 124 may be formed through a wire bonding process and may be a conductive wire containing a conductive material such as gold (Au) or copper (Cu). In embodiments, the first wire 124 may partially penetrate the first adhesive film AF1. A portion of the first wire 124 may be surrounded by the first adhesive film AF1, and the remaining portion of the first wire 124 may be surrounded by a molding layer 310.

Each of the second to fifth bonding pads 222, 242, 262, and 282 and the corresponding one of the plurality of conductive pads 112 may be electrically connected to each other by the second to fifth wires 224′, 244′, 264′, and 284′. The second to fifth wires 224, 244, 264, and 284 may be formed through a wire bonding process and may be conductive wires including a conductive material such as gold (Au) or copper (Cu). In embodiments, the second to fifth wires 224′, 244′, 264′, and 284′ may be surrounded by the molding layer 310.

In some example embodiments, the second semiconductor chip 220 may include a recess RS1, and an upper portion of the first semiconductor chip 120 may be disposed within the recess RS1. The recess RS1 may overlap the top of the first semiconductor chip 120 in a horizontal direction (e.g., X direction and/or Y direction) and may overlap the first semiconductor chip 120 in a vertical direction (e.g., Z direction). The detailed description of the recess RS1 is similar to that described above with reference to FIGS. 1A, 1B, and 2.

In some example embodiments, the third semiconductor chip 240 may overlap the upper portion of the second semiconductor chip 220 in the horizontal direction (e.g., the X direction and/or the Y direction), the fourth semiconductor chip 260 may overlap the upper portion of the third semiconductor chip 240 in the horizontal direction (e.g., the X direction and/or the Y direction), and the fifth semiconductor chip 280 may overlap the upper portion of the fourth semiconductor chip 260 in the horizontal direction (e.g., the X direction and/or the Y direction).

In some example embodiments, the third semiconductor chip 240, fourth semiconductor chip 260, and fifth semiconductor chip 280 may each include interlayer recesses RS1a, RS1b, and RS1c. Each of the interlayer recesses RS1a, RS1b, and RS1c may be formed on the second surface of each of the third to fifth semiconductor chips 240, 260, and 280.

The upper portion of the semiconductor chip bonded to each of the third to fifth semiconductor chips 240, 260, and 280 may be disposed within each of the interlayer recesses RS1a, RS1b, and RS1c. For example, the upper portion of the second semiconductor chip 220 may be disposed in the first interlayer recess RS1a of the third semiconductor chip 240, and the upper portion of the third semiconductor chip 240 may be disposed in the second interlayer recess RS1b of the fourth semiconductor chip 260, and the upper portion of the fourth semiconductor chip 260 may be disposed in the third interlayer recess RS1c of the fifth semiconductor chip 280.

Each of the interlayer recesses RS1a, RS1b, and RS1c may overlap the upper portion of a semiconductor chip bonded to a corresponding one of the third to fifth semiconductor chips 240, 260, and 280 in the horizontal direction (e.g., the X direction and/or the Y direction) and may overlap a portion of the semiconductor chip bonded to a corresponding of the third to fifth semiconductor chips 240, 260, and 280 in the vertical direction (e.g., the Z direction).

In the third to fifth semiconductor chips 240, 260, and 280, the thickness of the portion that overlaps in the vertical direction (e.g., the Z direction) with a corresponding one of the interlayer recesses RS1a, RS1b, and RS1c thereof may be thinner than the thickness of the portion that does not overlap in the vertical direction (e.g., the Z direction) with the corresponding one of the interlayer recesses RS1a, RS1b, and RS1c. In other words, the thickness of the portion of the third semiconductor chip 240 that overlaps the second semiconductor chip 220 in the vertical direction (e.g., the Z direction) may be thinner than the thickness of the portion of the third semiconductor chip 240 that does not overlap the second semiconductor chip 220 in the vertical direction (e.g., the Z direction), the thickness of the portion of the fourth semiconductor chip 260 that overlaps the third semiconductor chip 240 in the vertical direction (e.g., the Z direction) may be thinner than the thickness of the portion of the fourth semiconductor chip 260 that does not overlap the third semiconductor chip 240 in the vertical direction (e.g., the Z direction), and the thickness of the portion of the fifth semiconductor chip 280 that overlaps the fourth semiconductor chip 260 in the vertical direction (e.g., the Z direction) may be thinner than the thickness of the portion of the fifth semiconductor chip 280 that does not overlap the fourth semiconductor chip 260 in the vertical direction (e.g., the Z direction).

Each of the interlayer recesses RS1a, RS1b, and RS1c may include a sidewall opposite to a sidewall adjacent to a corresponding one of the third bonding pad 242, fourth bonding pad 262, and fifth bonding pad 282 corresponding to the third semiconductor chip 240, fourth semiconductor chip 260, and fifth semiconductor chip 280. The sidewalls of each interlayer recesses RS1a, RS1b, and RS1c may overlap the package substrate 110 in the vertical direction (e.g., Z direction).

Between a sidewall of the first interlayer recess RS1a and a sidewall of the second semiconductor chip 220 adjacent thereto, between a sidewall of the second interlayer recess RS1b and a sidewall of the third semiconductor chip 240 adjacent thereto, and between the sidewall of the third interlayer recess RS1c and the sidewall of the fourth semiconductor chip 260 adjacent thereto, a wire for wire bonding is not interposed. Thus, when forming each of interlayer recesses RS1a, RS1b, and RS1c, there is no need to consider the width of the wire extending between a sidewall of the first interlayer recess RS1a and a sidewall of the second semiconductor chip 220 adjacent thereto, between a sidewall of the second interlayer recess RS1b and a sidewall of the third semiconductor chip 240 adjacent thereto, and between the sidewall of the third interlayer recess RS1c and one sidewall of the fourth semiconductor chip 260 adjacent thereto. Accordingly, the sidewall of the first interlayer recess RS1a and the sidewall of the second semiconductor chip 220 adjacent thereto, a sidewall of the second interlayer recess RS1b and a sidewall of the third semiconductor chip 240 adjacent thereto, and the sidewall of the third interlayer recess RS1c and one sidewall of the fourth semiconductor chip 260 adjacent thereto do not have to be separate from each other, but may be in contact to each other.

The horizontal width of each interlayer recesses RS1a, RS1b, and RS1c may be less than the horizontal width of each of the second semiconductor chip 220, the third semiconductor chip 240, and the fourth semiconductor chip 260. In addition, the vertical height of each interlayer recesses RS1a, RS1b, and RS1c may be equal to or less than the vertical height of the semiconductor substrate constituting each of the third to fifth semiconductor chips 240, 260, and 280.

In addition, the shapes of each of interlayer recesses RS1a, RS1b, and RS1c may be of various configurations and are not limited to that shown. In some example embodiments, the sidewalls of each interlayer recess RS1a, RS1b, and RS1c may be formed as an inclined surface, similar to the recess RS1. In some other example embodiments, the sidewall of each interlayer recess RS1a, RS1b, and RS1c may include a curved surface or a curved surface similar to the recess RS2 shown in FIG. 3. In some other example embodiments, the sidewalls of each interlayer recess RS1a, RS1b, and RS1c may be formed as a plane extending in the vertical direction Z, similar to the recessed portion RS3 shown in FIG. 4.

Because the semiconductor package 40 according to the embodiments includes each interlayer recess RS1a, RS1b, and RS1c, it is possible to provide a semiconductor package with improved integration by reducing the vertical height.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a first semiconductor chip;
a second semiconductor chip on the first semiconductor chip;
an adhesive film between the first semiconductor chip and the second semiconductor chip; and
a molding layer covering a sidewall of the first semiconductor chip, a sidewall of the second semiconductor chip, and a sidewall of the adhesive film,
wherein the second semiconductor chip includes a recess,
the recess overlaps an upper portion of the first semiconductor chip in a horizontal direction, and
the molding layer overlaps a lower portion of the first semiconductor chip in the horizontal direction.

2. The semiconductor package of claim 1,
wherein the recess overlaps at least a portion of the first semiconductor chip in a vertical direction, and
the molding layer overlaps the remaining portion of the first semiconductor chip in the vertical direction.

3. The semiconductor package of claim 1,
wherein a horizontal width of the first semiconductor chip is less than a horizontal width of the second semiconductor chip,
a horizontal width of the recess is greater than the horizontal width of the first semiconductor chip and less than the horizontal width of the second semiconductor chip.

4. The semiconductor package of claim 1, wherein the second semiconductor chip comprises,
a semiconductor substrate, and
a semiconductor device layer on the semiconductor substrate, and
a vertical height of the recess is equal to or less than a vertical height of the semiconductor substrate of the second semiconductor chip.

5. The semiconductor package of claim 1, further comprising
a package substrate below the first semiconductor chip and supporting the first semiconductor chip; and
a wire electrically connecting the first semiconductor chip to the package substrate.

6. The semiconductor package of claim 5, wherein the wire extends between a sidewall of the recess and the sidewall of the first semiconductor chip.

7. The semiconductor package of claim 5, wherein a portion of the wire is surrounded by the adhesive film.

8. The semiconductor package of claim 1, wherein a sidewall of the recess is spaced apart from the sidewall of the first semiconductor chip.

9. The semiconductor package of claim 1, wherein a sidewall of the recess is spaced within 100 micrometers to 300 micrometers from the sidewall of the first semiconductor chip.

10. The semiconductor package of claim 1, wherein a sidewall of the recess extends along the sidewall of the first semiconductor chip to face the sidewall of the first semiconductor chip.

11. A semiconductor package comprising:
a package substrate;
a first semiconductor chip on an upper surface of the package substrate;
a first adhesive film between the upper surface of the package substrate and a lower surface of the first semiconductor chip;
a second semiconductor chip on an upper surface of the first semiconductor chip; and
a second adhesive film between the upper surface of the first semiconductor chip and a lower surface of the second semiconductor chip,
wherein the first semiconductor chip includes a first conductive pad on the upper surface of the first semiconductor chip,
the second semiconductor chip includes a second conductive pad on the upper surface of the second semiconductor chip, and
at least a portion of the first semiconductor chip overlaps the second semiconductor chip in a horizontal direction.

12. The semiconductor package of claim 11, wherein
the first semiconductor chip comprises,
a first semiconductor substrate; and
a first semiconductor device layer on the first semiconductor substrate,
the second semiconductor chip comprises,
a second semiconductor substrate defining a recess at a lower surface thereof; and
a second semiconductor device layer on the second semiconductor substrate, and
a portion of the first semiconductor chip overlaps the second semiconductor substrate in the horizontal direction.

13. The semiconductor package of claim 12, wherein a bottom of the recess in a vertical direction is at a different level in the vertical direction from a portion of the lower surface of the second semiconductor chip that surrounds the recess.

14. The semiconductor package of claim 11, further comprising
a first wire extending from an upper surface of the first semiconductor chip, partially penetrating the second adhesive film, and extending to the package substrate; and
a second wire extending from the lower surface of the second semiconductor chip to the package substrate.

15. The semiconductor package of claim 11, wherein a thickness of the second adhesive film is greater than a thickness of the first adhesive film.

16. The semiconductor package of claim 11, further comprising:
a third semiconductor chip on the second semiconductor chip,
wherein a horizontal width of the second semiconductor chip is same as a horizontal width of the third semiconductor chip, and
a sidewall of the second semiconductor chip is aligned on a same plane as a sidewall of the third semiconductor chip.

17. A semiconductor package comprising:
A package substrate;
a first semiconductor chip on the package substrate;
a second semiconductor chip on the first semiconductor chip; and
a third semiconductor chip on the second semiconductor chip,
wherein a horizontal width of the first semiconductor chip is less than a horizontal width of the second semiconductor chip,
the horizontal width of the second semiconductor chip is same as a horizontal width of the third semiconductor chip,
the second semiconductor chip overlaps an upper portion of the first semiconductor chip in a horizontal direction, and
the third semiconductor chip overlaps an upper portion of the second semiconductor chip in the horizontal direction.

18. The semiconductor package of claim 17, wherein
the third semiconductor chip comprises,
a semiconductor substrate, and
a semiconductor device layer on the semiconductor substrate, and
the semiconductor substrate of the third semiconductor chip overlaps the upper portion of the second semiconductor chip in the horizontal direction.

19. The semiconductor package of claim 17, wherein a thickness of a portion of the third semiconductor chip that overlaps the second semiconductor chip in a vertical direction is less than a thickness of a remaining portion of the third semiconductor chip that surrounds the portion of the third semiconductor chip.

20. The semiconductor package of claim 17, wherein the second semiconductor chip is offset from the third semiconductor chip.
